(19) United States
(12) Patent Application Publication
(10) Pub. No.: US 2020/0091341 A1
(43) Pub. Date: Mar. 19, 2020

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yasunori Iwatsu, Chigasaki Kanagawa (JP); Hirofumi Kawai, Yokohama Kanagawa (JP)

(21) Appl. No.: 16/353,495

(22) Filed: Mar. 14, 2019

(30) Foreign Application Priority Data
Sep. 18, 2018 (JP) 2018-173773

(51) Int. Cl. H01L 29/78; H01L 29/16; H01L 29/66; H01L 27/088

(52) U.S. Cl. CPC H01L 29/7816; H01L 29/16; H01L 27/088; H01L 29/6659; H01L 29/66681

(57) ABSTRACT

A semiconductor device includes a first semiconductor layer of a first conductivity type, a first element including a second semiconductor layer of a second conductivity type, a second element including a third semiconductor layer of the second conductivity type, a first conductive member disposed in the first semiconductor layer between the first element and the second element, and a first semiconductor region of the second conductivity type provided inside the first semiconductor layer and contacting the first conductive member. A portion of the first element and a portion of the second element are formed in an upper layer portion of the first semiconductor layer. An upper end of the first conductive member is positioned higher than an upper end of the second semiconductor layer. A lower end of the first conductive member is positioned lower than lower ends of the second and third semiconductor layers.

### CROSS-REFERENCE TO RELATED APPLICATIONS

This application is based upon and claims the benefit of priority from Japanese Patent Application No. 2018-173773, filed on Sep. 18, 2018; the entire contents of which are incorporated herein by reference.

### FIELD

Embodiments relate to a semiconductor device.

### BACKGROUND

Semiconductor devices have been developed in which multiple elements are formed in a semiconductor substrate. It is desirable to downsize such semiconductor devices.

### BRIEF DESCRIPTION OF THE DRAWINGS

FIG. 1A is a plan view showing a semiconductor device according to a first embodiment; and FIG. 1B is a cross-sectional view along line A-A′ shown in FIG. 1A;

FIG. 2A is a plan view showing a semiconductor device according to a comparative example; and FIG. 2B is a cross-sectional view along line B-B′ shown in FIG. 2A;

FIGS. 3A to 3D show simulation results of a test example;

FIG. 4 is a cross-sectional view showing a semiconductor device according to a second embodiment;

FIGS. 5A to 5D and FIGS. 6A to 6D are cross-sectional views showing a method for manufacturing the semiconductor device according to the second embodiment;

FIG. 7 is a cross-sectional view showing a semiconductor device according to a third embodiment;

FIG. 8 is a plan view showing a semiconductor device according to a fourth embodiment;

FIG. 9 is a cross-sectional view showing the semiconductor device according to the fourth embodiment;

FIG. 10 is a cross-sectional view showing a semiconductor device according to a fifth embodiment;

FIGS. 11A to 11D, FIGS. 12A to 12C, and FIGS. 13A to 13C are cross-sectional views showing a method for manufacturing the semiconductor device according to the fifth embodiment;

FIG. 14 is a plan view showing a semiconductor device according to a sixth embodiment; and

FIG. 15 is a plan view showing a method for manufacturing the semiconductor device according to the sixth embodiment.

### DETAILED DESCRIPTION

A semiconductor device according to an embodiment, includes a first semiconductor layer of a first conductivity type, a first element including a second semiconductor layer of a second conductivity type, a second element including a third semiconductor layer of the second conductivity type, a first conductive member disposed in the first semiconductor layer, and a first semiconductor region of the second conductivity type. At least a portion of the first element is formed in an upper layer portion of the first semiconductor layer. At least a portion of the second element is formed in an upper layer portion of the first semiconductor layer. The first conductive member is disposed between the first element and the second element.

An upper end of the first conductive member is positioned higher than an upper end of the second semiconductor layer. A lower end of the first conductive member is positioned lower than a lower end of the second semiconductor layer and a lower end of the third semiconductor layer. The first semiconductor region is provided inside the first semiconductor layer and contacts the first conductive member.

### First Embodiment

A first embodiment will now be described.

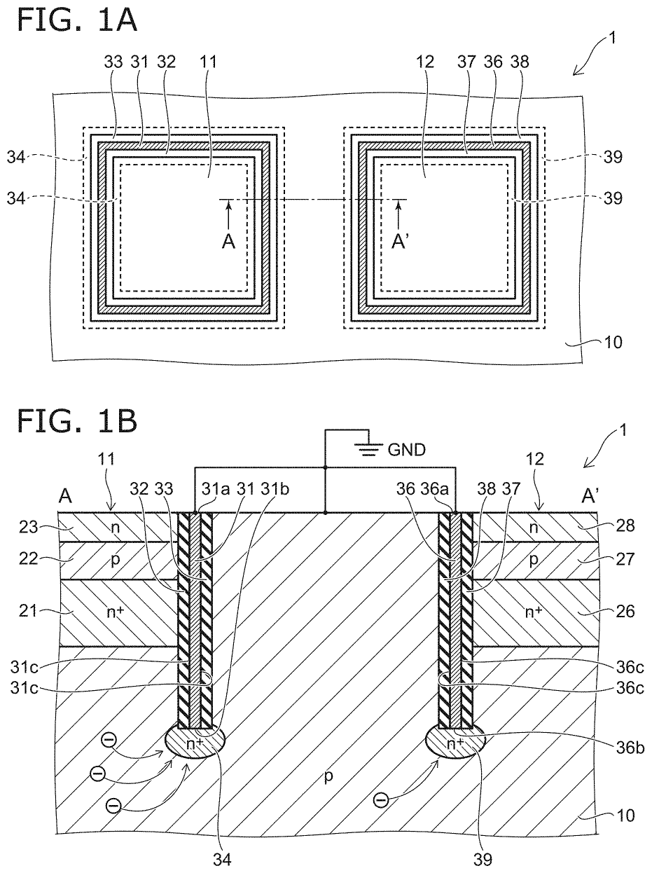

FIG. 1A is a plan view showing a semiconductor device according to the embodiment; and FIG. 1B is a cross-sectional view along line A-A′ shown in FIG. 1A.

The drawings are schematic; and components are enhanced or not illustrated as appropriate. The dimensional ratios and the like of the components do not always match between the drawings. This is similar for the other drawings described below as well.

As shown in FIGS. 1A and 1B, a silicon substrate 10 of a p-conductivity type is provided in the semiconductor device 1 according to the embodiment. An element 11 and an element 12 are formed in the upper layer portion of the silicon substrate 10 and on the silicon substrate 10. The element 11 and the element 12 may be, for example, MOSFET (Metal-Oxide-Semiconductor Field-Effect Transistors) or may be, for example, DMOSs (Double-Diffused MOSFETs). The element 11 and the element 12 may be the same type of element or may be different types of elements. The element 12 may be, for example, an analog element.

In the element 11, an n⁺-type buried layer 21 of an n⁺-conductivity type is provided in the upper layer portion of the silicon substrate 10; a p-type layer 22 of the p-conductivity type is provided on the n⁺-type buried layer 21; and an n-type layer 23 of the n-conductivity type is provided on the p-type layer 22. At least a portion of the n-type layer 23 is exposed at the upper surface of the silicon substrate 10. The notation of the “n⁺-type” indicates that the conductivity type is the n-type; and the concentration of an impurity that forms donors (hereinbelow, called an “n-type impurity”) is higher than that of the “n-type.” Similarly, the notation of the “p⁺-type” indicates that the conductivity type is the p-type; and the concentration of an impurity that forms acceptors (hereinbelow, called a “p-type impurity”) is higher than that of the “p-type.”

Similarly, in the element 12, an n⁺-type buried layer 26 is provided in the upper layer portion of the silicon substrate 10; a p-type layer 27 is provided on the n⁺-type buried layer 26; and an n-type layer 28 is provided on the p-type layer 27. At least a portion of the n-type layer 28 is exposed at the upper surface of the silicon substrate 10.

A conductive member 31 is provided at the periphery of the element 11 when viewed from above. The conductive member 31 is formed of a conductive material, e.g., a metal or polysilicon including an n-type impurity. An upper end 31a of the conductive member 31 is exposed at the upper surface of the silicon substrate 10; and a lower end 31b of the conductive member 31 is positioned lower than the lower end of the n⁺-type buried layer 21 and the lower end of the n⁺-type buried layer 26 inside the silicon substrate 10.

Insulating films 32 and 33 are provided between the silicon substrate 10 and side surfaces 31c of the conductive member 31. However, the insulating films 32 and 33 do not cover the lower end 31b of the conductive member 31. The thicknesses of the insulating films 32 and 33 are thicknesses that can ensure the breakdown voltage between the conductive member 31 and the element 11.

An n⁺-type region 34 is provided directly under the conductive member 31 inside the silicon substrate 10. The n⁺-type region 34 contacts the lower end 31b of the conductive member 31. Thereby, the silicon substrate 10 can be connected to the conductive member 31 via the n⁺-type region 34. The n⁺-type region 34 also may contact the lower ends of the insulating films 32 and 33.

When viewed from above, the configurations of the conductive member 31, the insulating film 32, the insulating film 33, and the n⁺-type region 34 are frame-like configurations surrounding the element 11. Accordingly, portions of the conductive member 31, the insulating film 32, the insulating film 33, and the n⁺-type region 34 are disposed between the element 11 and the element 12.

Similarly, a conductive member 36 is provided at the periphery of the element 12 when viewed from above. The conductive member 36 also is formed of a conductive material, e.g., a metal or polysilicon including an n-type impurity. An upper end 36a of the conductive member 36 is exposed at the upper surface of the silicon substrate 10; and a lower end 36b of the conductive member 36 is positioned lower than the lower end of the n⁺-type buried layer 21 and the lower end of the n⁺-type buried layer 26 inside the silicon substrate 10.

Insulating films 37 and 38 are provided between the silicon substrate 10 and side surfaces 36c of the conductive member 36. However, the insulating films 37 and 38 do not cover the lower end 36b of the conductive member 36. An n⁺-type region 39 is provided directly under the conductive member 36 inside the silicon substrate 10. The n⁺-type region 39 contacts the lower end 36b of the conductive member 36. Thereby, the silicon substrate 10 can be connected to the conductive member 36 via the n⁺-type region 39.

When viewed from above, the configurations of the conductive member 36, the insulating film 37, the insulating film 38, and the n⁺-type region 39 are frame-like configurations surrounding the element 12. Accordingly, portions of the conductive member 36, the insulating film 37, the insulating film 38, and the n⁺-type region 39 are disposed between the element 11 and the element 12.

An operation of the semiconductor device 1 according to the embodiment will now be described.

The silicon substrate 10 is connected to a reference potential, e.g., a ground potential GND. The upper end 31a of the conductive member 31 and the upper end 36a of the conductive member 36 also are connected to the ground potential GND. A negative freewheeling current flows into the n-type layer 23 of the element 11 due to an impedance element connected to the n-type layer 23.

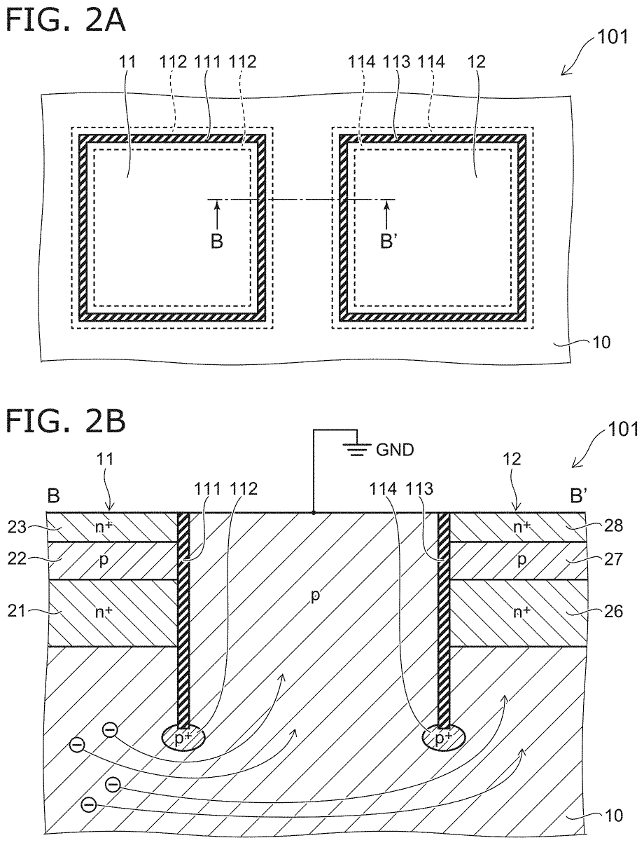

When the negative freewheeling current is input to the n-type layer 23 of the element 11, the parasitic n-p-n transistor that is made of the n-type layer 23, the p-type layer 22, and the n⁺-type buried layer 21 conducts; thereby, the parasitic p-n-p transistor that is made of the p-type layer 22, the n⁺-type buried layer 21, and the silicon substrate 10 conducts. As a result, electrons are introduced from the element 11 to the silicon substrate 10. In FIG. 1B, the electrons are shown by “−” (negative) symbols surrounded with circles. This is similar for FIG. 2B described below as well.

Because the conductive member 31 and the n⁺-type region 34 are provided at the periphery of the element 11 and the ground potential GND is applied, the greater part of the electrons introduced to the silicon substrate 10 are ejected to the ground potential GND via the n⁺-type region 34 and the conductive member 31. Also, the greater part of the electrons not absorbed by the n⁺-type region 34 are ejected to the ground potential GND via the n⁺-type region 39 and the conductive member 36.

Effects of the embodiment will now be described.

In the semiconductor device 1 as described above, the greater part of the electrons introduced to the silicon substrate 10 from the element 11 are ejected to the ground potential GND via the n⁺-type region 34 and the conductive member 31. Also, the greater part of the electrons not absorbed by the n⁺-type region 34 are ejected to the ground potential GND via the n⁺-type region 39 and the conductive member 36. Therefore, the electrons that are introduced to the silicon substrate 10 from the element 11 can be suppressed from reaching the element 12; and the effects on the operation of the element 12 can be suppressed. As a result, the distance between the element 11 and the element 12 can be shorter; and the semiconductor device 1 can be downsized.

A positive potential may be applied to the upper end 31a of the conductive member 31 and the upper end 36a of the conductive member 36 as the reference potential. The electrons inside the silicon substrate 10 can be absorbed more reliably thereby.

### Comparative Example

A comparative example will now be described.

FIG. 2A is a plan view showing a semiconductor device according to the comparative example; and FIG. 2B is a cross-sectional view along line B-B′ shown in FIG. 2A.

In the semiconductor device 101 according to the comparative example as shown in FIGS. 2A and 2B, the conductive member 31, the insulating films 32 and 33, and the n⁺-type region 34 are not provided at the periphery of the element 11; instead, for example, an insulating member 111 that is made of an insulating material such as silicon oxide or the like is provided. A p⁺-type region 112 is provided directly under the insulating member 111. The p⁺-type region 112 contacts the lower end of the insulating member 111.

Similarly, the conductive member 36, the insulating films 37 and 38, and the n⁺-type region 39 are not provided at the periphery of the element 12; instead, an insulating member 113 that is made of an insulating material is provided. A p⁺-type region 114 is provided directly under the insulating member 113. The p⁺-type region 114 contacts the lower end of the insulating member 113. The silicon substrate 10 is connected to the ground potential GND.

In the semiconductor device 101, when the negative freewheeling current is input to the n-type layer 23 of the element 11 and the electrons are introduced to the silicon substrate 10, a portion of the electrons are ejected to the ground potential GND via the silicon substrate 10; but the remainder flows into the element 12 and causes fluctuation of the potential of the n⁺-type buried layer 26. As a result, a misoperation may occur due to the instability of the operation of the element 12.

### Test Example

A test example showing effects of the first embodiment will now be described.

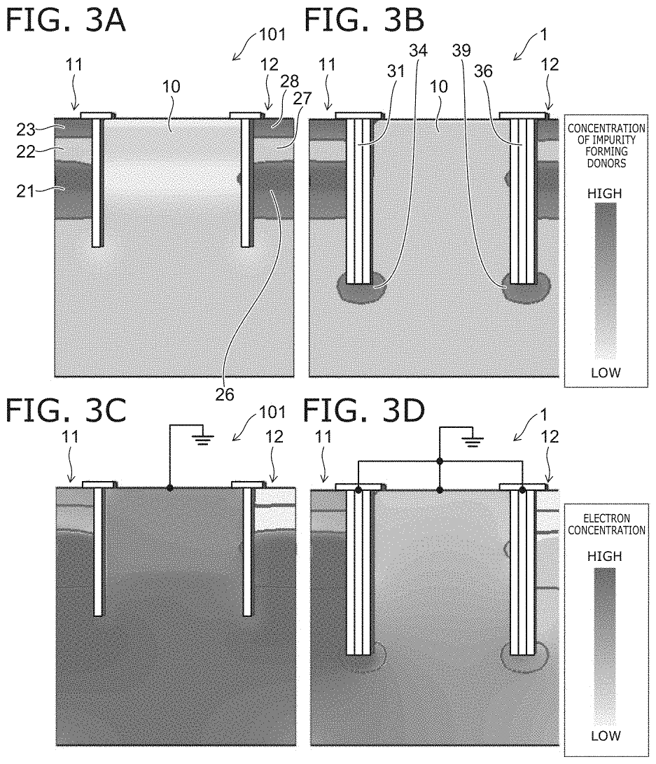

FIGS. 3A to 3D show simulation results of the test example.

FIG. 3A shows the concentration distribution of the n-type impurity of the semiconductor device 101 according to the comparative example; FIG. 3B shows the concentration distribution of the n-type impurity of the semiconductor device according to the first embodiment; FIG. 3C shows the concentration distribution of the electrons of the semiconductor device 101 according to the comparative example; and FIG. 3D shows the concentration distribution of the electrons of the semiconductor device 1 according to the first embodiment.

In the semiconductor device 101 according to the comparative example of the test example, a portion is provided in the silicon substrate 10 between the element 11 and the element 12 where the concentration of the p-type impurity is higher than that of the periphery. Therefore, the concentration of the n-type impurity of this portion is lower than that of the periphery.

In the test example, the electron concentration distribution was calculated by assuming a negative freewheeling current input to the element 11 in the state in which the ground potential GND is applied to the silicon substrate 10 and the conductive members 31 and 36.

In the semiconductor device 101 according to the comparative example as shown in FIG. 3C, a portion of the electrons flowing into the element 11 are ejected to the ground potential GND from the portion of the silicon substrate 10 between the element 11 and the element 12; but the greater part of the electrons flow into the n⁺-type buried layer 26 of the element 12. It is estimated that the operation of the element 12 becomes unstable due to the negative freewheeling current input to the element 11.

Conversely, in the semiconductor device 1 according to the first embodiment as shown in FIG. 3D, the greater part of the electrons flowing into the element 11 are absorbed by the n⁺-type region 34; a portion of the electrons is absorbed by the n⁺-type region 39; and almost none of the electrons reaches the n⁺-type buried layer 26 of the element 12. It is therefore estimated that the negative freewheeling current that is input to the element 11 substantially does not affect the operation of the element 12. The current that reaches the element 12 when the negative freewheeling current flows into the element 11 in the semiconductor device 1 is about 1/10000 of the same current in the semiconductor device 101.

### Second Embodiment

A second embodiment will now be described.

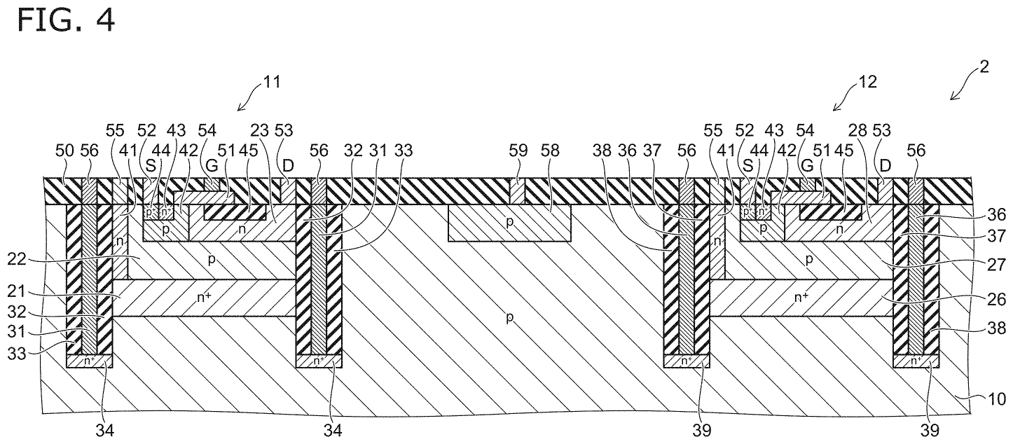

FIG. 4 is a cross-sectional view showing a semiconductor device according to the embodiment.

In the semiconductor device 2 according to the embodiment as shown in FIG. 4, p-channel DMOSs are provided as the element 11 and the element 12. The semiconductor device 2 is, for example, an LSI (large scale integrated circuit) in which the DMOSs are provided together.

In the element 11, a deep n-well 41 is provided on the n⁺-type buried layer 21. The deep n-well 41 contacts the n⁺-type buried layer 21 and the p-type layer 22. A p-well 42 is provided on the p-type layer 22. The p-well 42 contacts the p-type layer 22 and the n-type layer 23. The n-type layer 23 is a drift layer. A source region 43 of the n⁺-conductivity type and a back gate region 44 of the p⁺-conductivity type are provided on the p-well 42. A STI (Shallow Trench Isolation (element-separating insulating film)) 45 is provided in a portion on the n-type layer 23.

An inter-layer insulating film 50 that is made of, for example, silicon oxide is provided on the silicon substrate 10. A gate electrode 51 that is made of, for example, polysilicon is provided inside the inter-layer insulating film 50. A gate insulating film (not illustrated) is provided between the gate electrode 51 and the semiconductor portion including the n-type layer 23 and the p-well 42.

A source contact 52, a drain contact 53, a gate contact 54, a body contact 55, and a plug 56 that are made of, for example, metals are provided inside the inter-layer insulating film 50. The source contact 52 is connected to the source region 43 and the back gate region 44. The drain contact 53 is connected to the n-type layer 23. The gate contact 54 is connected to the gate electrode 51. The body contact 55 is connected to the deep n-well 41. The plug 56 is connected to the upper end 31a of the conductive member 31.

The configuration of the element 12 also is similar to that of the element 11. Namely, in the element 12, the deep n-well 41 is provided on the n⁺-type buried layer 26 and contacts the n⁺-type buried layer 26 and the p-type layer 27. The p-well 42 is provided on the p-type layer 27 and contacts the p-type layer 27 and the n-type layer 28. The n-type layer 28 is a drift layer. The n⁺-type source region 43 and the p⁺-type back gate region 44 are provided on the p-well 42. The STI 45 is provided in a portion on the n-type layer 28.

In the element 12 as well, the gate electrode 51, the source contact 52, the drain contact 53, the gate contact 54, the body contact 55, and the plug 56 are provided inside the inter-layer insulating film 50 and are connected similarly to those of the element 11.

A p-well 58 of the p-conductivity type is provided in the upper layer portion of the portion of the silicon substrate 10 between the element 11 and the element 12. The concentration of the p-type impurity in the p-well 58 is higher than the concentration of the p-type impurity in the silicon substrate 10. A plug 59 is provided inside the inter-layer insulating film 50 and connected to the p-well 58.

A method for manufacturing the semiconductor device according to the embodiment will now be described.

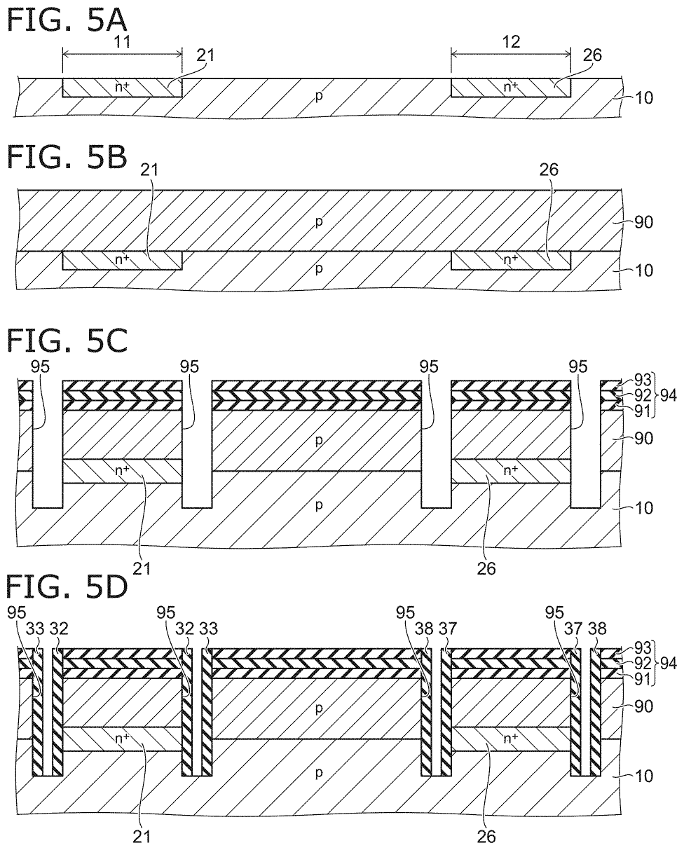

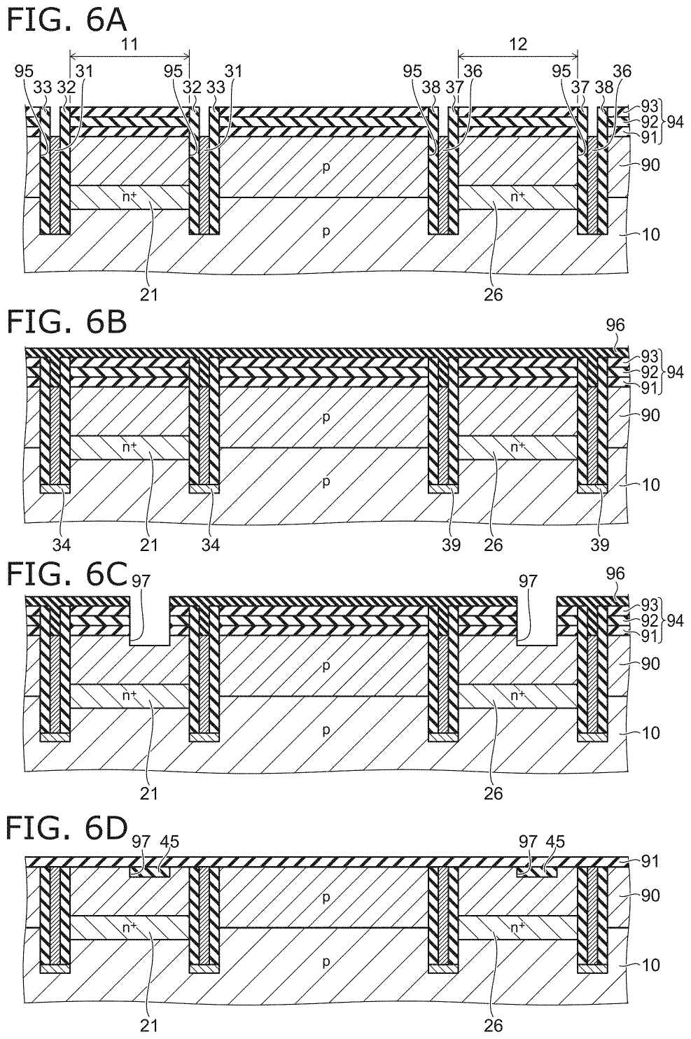

FIGS. 5A to 5D and FIGS. 6A to 6D are cross-sectional views showing the method for manufacturing the semiconductor device according to the embodiment.

First, as shown in FIG. 5A, the n⁺-type buried layers 21 and 26 are formed in the upper layer portion of the p-type silicon substrate 10. The n⁺-type buried layer 21 is formed in the region where the element 11 is to be formed; and the n⁺-type buried layer 26 is formed in the region where the element 12 is to be formed.

Then, as shown in FIG. 5B, a p-type epitaxial layer 90 is formed by epitaxially growing silicon on the silicon substrate 10.

Continuing as shown in FIG. 5C, a mask film 94 is formed by depositing a silicon oxide layer 91, a silicon nitride layer 92, and a silicon oxide layer 93 in this order on the epitaxial layer 90. Then, the mask film 94 is patterned. Then, a deep trench 95 is formed by performing RIE (Reactive Ion Etching) of the silicon using the patterned mask film 94 as a mask.

The deep trench 95 is formed in frame-like configurations surrounding the region where the element 11 is to be formed and the region where the element 12 is to be formed. The deep trench 95 pierces the epitaxial layer 90 and reaches the upper layer portion of the silicon substrate 10. As these processes are performed, the n-type impurity that is included in the n⁺-type buried layers 21 and 26 diffuses into the epitaxial layer 90; and the n⁺-type buried layers 21 and 26 elongate into the epitaxial layer 90.

Then, as shown in FIG. 5D, a thin silicon oxide layer is formed on the inner surface of the deep trench 95 by performing thermal oxidation treatment. Then, silicon oxide is deposited by CVD (Chemical Vapor Deposition). Then, the silicon oxide that is on the bottom surface of the deep trench 95 and on the upper surface of the mask film 94 is removed by performing RIE. Thereby, the insulating films 32, 33, 37, and 38 that have sidewall configurations are formed on the side surfaces of the deep trench 95.

Continuing as shown in FIG. 6A, polysilicon to which an n-type impurity such as phosphorus (P), arsenic (As), or the like is added is deposited by CVD. Then, etch-back of the polysilicon is performed by CMP (Chemical Mechanical Polishing) or CDE (Chemical Dry Etching). Thereby, the conductive members 31 and 36 are formed by causing the polysilicon to remain only inside the deep trench 95.

Then, as shown in FIG. 6B, a mask film 96 is formed by depositing silicon oxide by CVD. Then, heat treatment is performed. Thereby, the n-type impurity that is included inside the conductive members 31 and 36 diffuses into the silicon substrate 10; and the n⁺-type regions 34 and 39 are formed self-aligningly.

Continuing as shown in FIG. 6C, the mask film 96 is patterned to expose the region where the STI 45 is to be formed. Then, a recess 97 is formed in the upper surface of the epitaxial layer 90 by performing RIE of the silicon using the patterned mask film 96 as a mask.

Then, as shown in FIG. 6D, silicon oxide is deposited by CVD. Then, the upper surface is planarized by performing CMP using the silicon nitride layer 92 as a stopper. Then, the silicon nitride layer 92 is removed. Thereby, the STI 45 is formed inside the recess 97.

Continuing as shown in FIG. 4, the deep n-well 41, the p-well 42, the n-type layer 23, the source region 43, the back gate region 44, and the p-well 58 are formed by lithography and ion implantation. At this time, the remaining portion of the epitaxial layer 90 becomes the p-type layers 22 and 27. In FIG. 4, the epitaxial layer 90 in the region between the element 11 and the element 12 is illustrated as a portion of the silicon substrate 10. Then, the silicon oxide layer 91 is removed.

Then, the gate insulating film (not illustrated), the gate electrode 51, the source contact 52, the drain contact 53, the gate contact 54, the body contact 55, the plug 56, and the plug 59 are formed; and the inter-layer insulating film 50 is formed. Thus, the semiconductor device 2 according to the embodiment is manufactured.

When the negative freewheeling current is input via the drain contact 53 to the p-channel DMOS included in the element 11 of the embodiment, similarly to the first embodiment, the parasitic n-p-n transistor that is made of the n-type layer 23, the p-type layer 22, and the n⁺-type buried layer 21 conducts; thereby, the parasitic p-n-p transistor made of the p-type layer 22, the n⁺-type buried layer 21, and the silicon substrate 10 conducts; and the electrons are introduced to the silicon substrate 10.

The electrons are ejected to the ground potential via the n⁺-type region 34 and the conductive member 31 and ejected to the ground potential via the n⁺-type region 39 and the conductive member 36. Thus, because the n⁺-type region 34, the conductive member 31, the n⁺-type region 39, and the conductive member 36 are provided between the element 11 and the element 12, the inflow of the electrons into the element 12 can be suppressed; and the unstable operation of the element 12 can be suppressed.

Otherwise, the configuration, the operations, and the effects of the embodiment are similar to those of the first embodiment described above.

### Third Embodiment

A third embodiment will now be described.

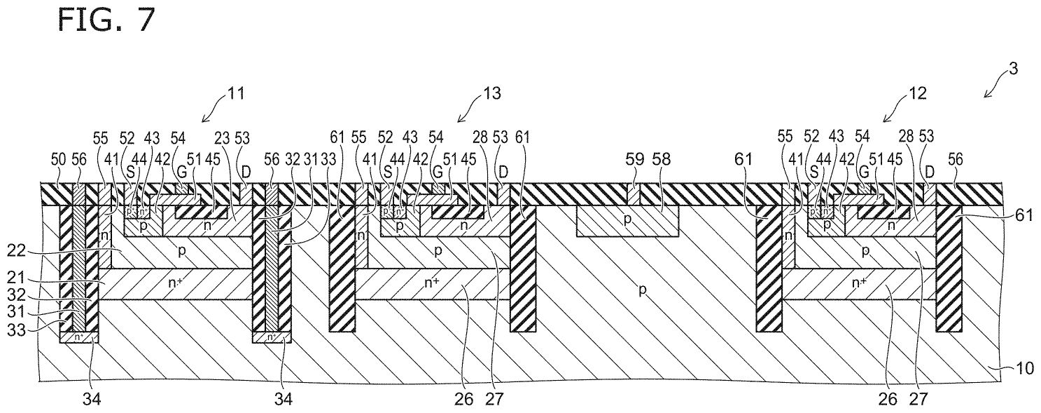

FIG. 7 is a cross-sectional view showing a semiconductor device according to the embodiment.

In the semiconductor device 3 according to the embodiment as shown in FIG. 7, an element 13 is provided between the element 11 and the element 12. The type of the element 13 is not particularly limited. FIG. 7 shows an example in which the element 13 also is a p-channel DMOS similar to the elements 11 and 12. The element 13 is, for example, a p-channel DMOS included in a high-side driver.

In the semiconductor device 3, the conductive member 31 and the n⁺-type region 34 are provided at the periphery of the element 11; but the conductive member 36 and the n⁺-type region 39 are not provided at the periphery of the element 12; instead, an insulating member 61 is provided. The insulating member 61 is provided also at the periphery of the element 13. For example, the insulating member 61 is made of an insulating material such as silicon oxide, etc. The configuration of the insulating member 61 is a frame-like configuration surrounding the element 12 or the element 13 when viewed from above. The lower end of the insulating member 61 is positioned lower than the lower end of the n⁺-type buried layer 21 and the lower end of the n⁺-type buried layer 26.

Similarly to the first and second embodiments, the circuit configuration of the semiconductor device 3 is such that there is a possibility that the negative freewheeling current may flow into the element 11; but the negative freewheeling current does not flow into the element 12 and the element 13.

In the embodiment, because the conductive member 31 and the n⁺-type region 34 are provided at the periphery of the element 11 into which the negative freewheeling current flows from the outside, the electrons that flow into the silicon substrate 10 due to the negative freewheeling current can be ejected via the n⁺-type region 34 and the conductive member 31. On the other hand, the element surface areas of the elements 12 and 13 are small because the conductive members are not provided at the peripheries of the element 12 and the element 13 into which the negative freewheeling current from the outside does not flow. Thereby, the semiconductor device 3 can be downsized even more.

Because the greater part of the electrons flowing into the element 11 is ejected by the n⁺-type region 34 and the conductive member 31, there is no problem in practice even though n⁺-type regions and conductive members are not provided at the peripheries of the element 12 and the element 13.

Also, because the n⁺-type regions are not provided for the elements 12 and 13 in the embodiment, latchup of the parasitic p-n-p-n thyristors can be avoided when these elements are used as high-side DMOSs.

Otherwise, the configuration, the manufacturing method, the operations, and the effects of the embodiment are similar to those of the first embodiment described above.

### Fourth Embodiment

A fourth embodiment will now be described.

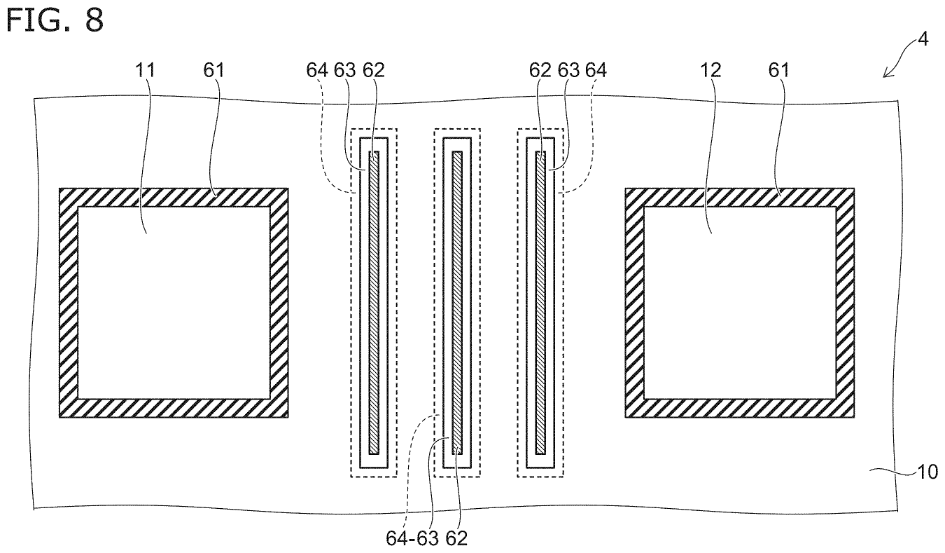

FIG. 8 is a plan view showing a semiconductor device according to the embodiment.

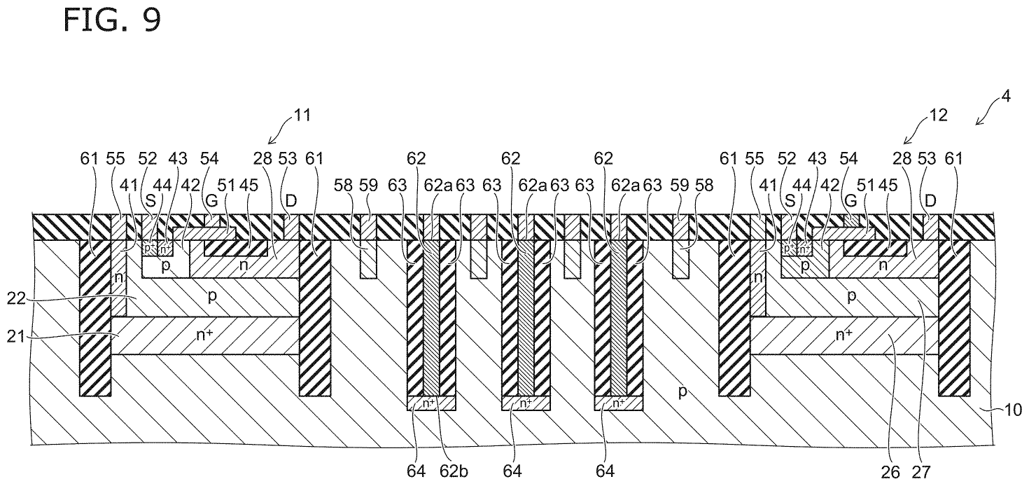

FIG. 9 is a cross-sectional view showing the semiconductor device according to the embodiment.

As shown in FIG. 8 and FIG. 9, the semiconductor device 4 according to the embodiment differs from the semiconductor device 2 according to the second embodiment described above (referring to FIG. 4) in that the conductive members, the insulating films, and the n⁺-type regions are not provided at the periphery of the element 11 and the periphery of the element 12; the insulating member 61 is provided; and a conductive member 62 is provided between the element 11 and the element 12.

The conductive member 62 is disposed between the insulating member 61 surrounding the element 11 and the insulating member 61 surrounding the element 12. The configuration of the conductive member 62 is a flat plate configuration spreading in a direction orthogonal to the direction from the element 11 toward the element 12. For example, three conductive members 62 are arranged to be parallel to each other. An insulating film 63 is provided to cover the side surface of the conductive member 62. An n⁺-type region 64 is provided directly under the conductive member 62 and contacts a lower end 62b of the conductive member 62.

The configuration of the insulating member 61 is as described in the third embodiment. For example, the conductive member 62 is made from a conductive material such as a metal, polysilicon including an n-type impurity, etc.; an upper end 62a of the conductive member 62 is exposed at the upper surface of the silicon substrate 10; and the lower end 62b is positioned lower than the lower end of the n⁺-type buried layer 21 and the lower end of the n⁺-type buried layer 26.

According to the embodiment, the elements 11 and 12 can be smaller compared to those of the second embodiment because the insulating members 61 are provided instead of the conductive members, the insulating films, and the n⁺-type regions at the periphery of the element 11 and the periphery of the element 12. On the other hand, because the conductive member 62, the insulating film 63, and the n⁺-type region 64 are provided between the element 11 and the element 12, the movement of the electrons from the element 11 to the element 12 can be suppressed by an effect similar to that of the second embodiment.

Otherwise, the configuration, the manufacturing method, the operations, and the effects of the embodiment are similar to those of the second embodiment described above.

Although an example is shown in the embodiment in which three conductive members 62 are provided to be parallel to each other, this is not limited thereto; and the number of the conductive members 62 may be two or less, or four or more. The configuration of the conductive member 62 is not limited to a flat plate configuration and may be, for example, bent along the outer edge of the element 11 or the element 12.

### Fifth Embodiment

A fifth embodiment will now be described.

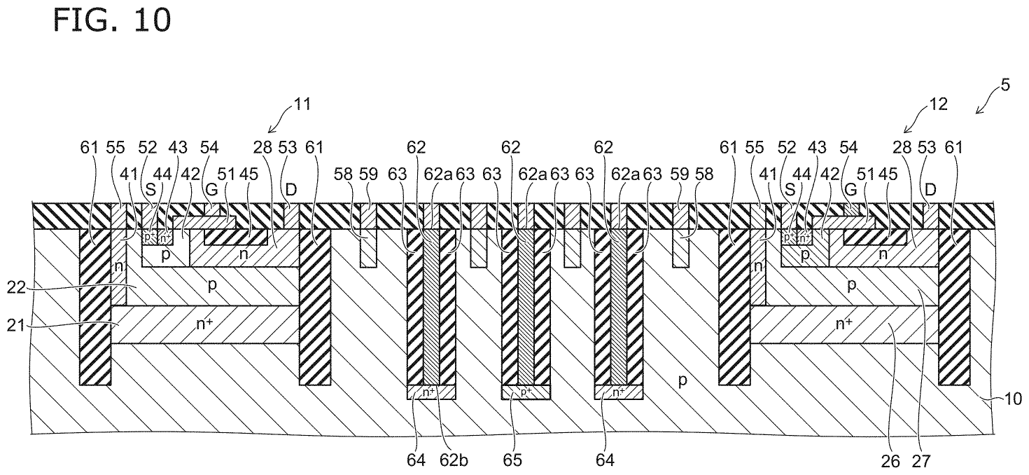

FIG. 10 is a cross-sectional view showing a semiconductor device according to the embodiment.

As shown in FIG. 10, the semiconductor device 5 according to the embodiment differs from the semiconductor device 4 according to the fourth embodiment described above (referring to FIG. 8 and FIG. 9) in that a portion of the n⁺-type regions 64 is replaced with a p⁺-type region 65.

The conductivity type of the p⁺-type region 65 is the p-type; and the p-type impurity concentration of the p⁺-type region 65 is higher than the p-type impurity concentration of the silicon substrate 10. The p⁺-type region 65 is provided directly under a portion of the conductive members 62 and contacts the lower end 62b of the conductive member 62. The ground potential is applied also to the p⁺-type region 65 via the conductive member 62.

A method for manufacturing the semiconductor device according to the embodiment will now be described.

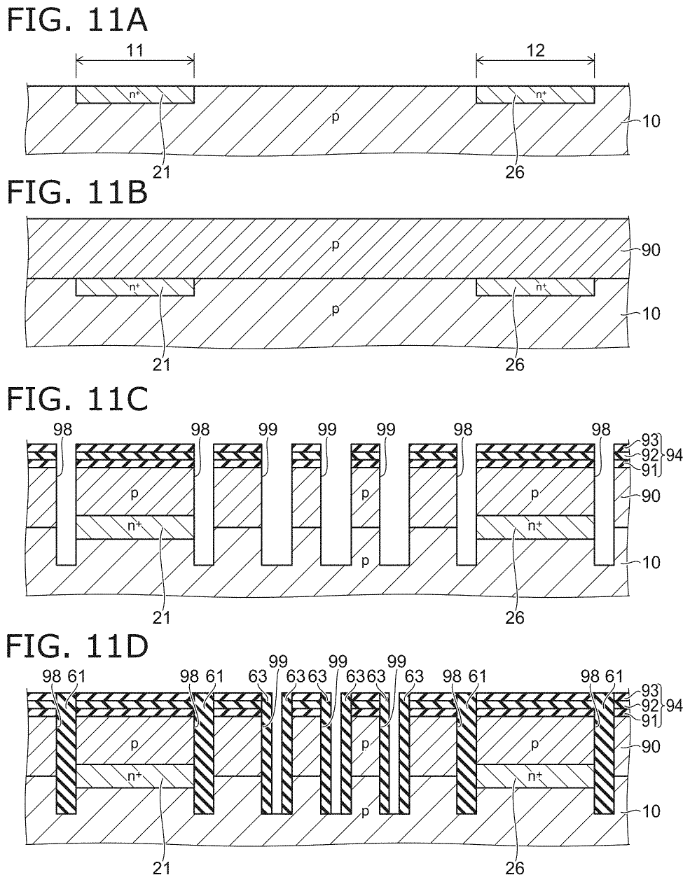

FIGS. 11A to 11D, FIGS. 12A to 12C, and FIGS. 13A to 13C are cross-sectional views showing the method for manufacturing the semiconductor device according to the embodiment.

First, as shown in FIG. 11A, the n⁺-type buried layers 21 and 26 are formed in the upper layer portion of the p-type silicon substrate 10.

Then, as shown in FIG. 11B, the p-type epitaxial layer 90 is formed by epitaxially growing silicon on the silicon substrate 10.

Continuing as shown in FIG. 11C, the mask film 94 is formed by depositing the silicon oxide layer 91, the silicon nitride layer 92, and the silicon oxide layer 93 in this order on the epitaxial layer 90. Then, the mask film 94 is patterned. Then, deep trenches 98 and 99 are formed by performing RIE of the silicon using the patterned mask film 94 as a mask.

At this time, the deep trench 98 is formed in frame-like configurations surrounding the region where the element 11 is to be formed and the region where the element 12 is to be formed. On the other hand, the deep trench 99 is formed in a line configuration between the region where the element 11 is to be formed and the region where the element 12 is to be formed.

For example, three of the deep trenches 99 are formed to extend in a direction orthogonal to the direction from the element 11 toward the element 12. The width of the deep trench 99 is set to be wider than the width of the deep trench 98 and is, for example, about the same as that of the deep trench 95 of the second embodiment (referring to FIG. 5C). The deep trenches 98 and 99 pierce the epitaxial layer 90 and enter the upper layer portion of the silicon substrate 10. Also, as these processes are performed, the n-type impurity that is included in the n⁺-type buried layers 21 and 26 diffuses into the epitaxial layer 90; and the n⁺-type buried layers 21 and 26 elongate into the epitaxial layer 90.

Then, as shown in FIG. 11D, a thin silicon oxide layer is formed on the inner surface of the deep trenches 98 and 99 by performing thermal oxidation treatment. Then, silicon oxide is deposited by CVD. At this time, the silicon oxide fills the entire interior of the deep trench 98 because the deep trench 98 is narrow. On the other hand, because the deep trench 99 is wide, the silicon oxide is deposited on the inner surface of the deep trench 99 but does not fill the entire interior of the deep trench 99.

Continuing, RIE is performed. The silicon oxide that is on the bottom surface of the deep trench 99 and on the upper surface of the mask film 94 is removed thereby. On the other hand, the silicon oxide that is inside the deep trench 98 is substantially not removed because the interior of the deep trench 98 is filled with silicon oxide. Thus, the insulating film 63 that has the sidewall configuration is formed on the side surface of the deep trench 99. On the other hand, the insulating member 61 is formed of the silicon oxide remaining in the deep trench 98.

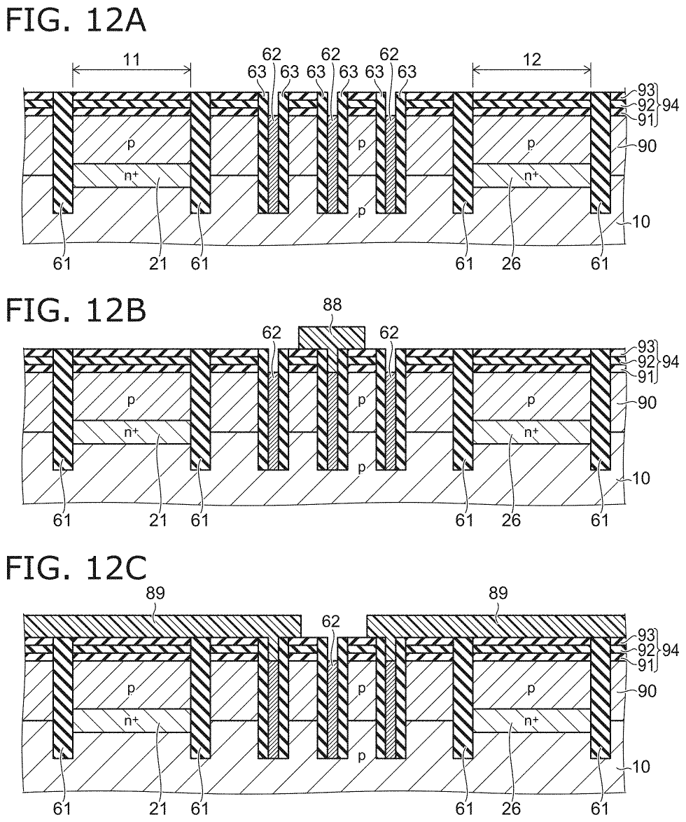

Then, as shown in FIG. 12A, undoped polysilicon to which an impurity is not added is deposited by CVD. Then, etch-back of the polysilicon is performed by CMP or CDE. Thereby, the conductive member 62 is formed by causing the polysilicon to remain only inside the deep trench 99.

Continuing as shown in FIG. 12B, a resist mask 88 is formed so that the region where the n⁺-type region 64 is to be formed is exposed. Then, an n-type impurity such as phosphorus, arsenic, or the like is ion-implanted using the resist mask 88 as a mask. Then, the resist mask 88 is removed.

Then, as shown in FIG. 12C, a resist mask 89 is formed so that the region where the p⁺-type region 65 is to be formed is exposed. Then, a p-type impurity such as boron (B) or the like is ion-implanted using the resist mask 89 as a mask. Then, the resist mask 89 is removed.

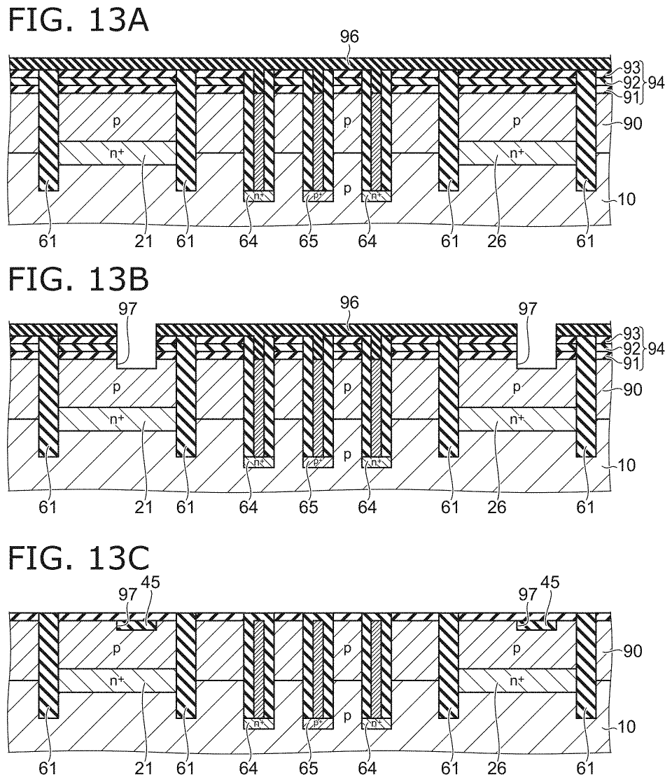

Continuing as shown in FIG. 13A, the mask film 96 is formed by depositing silicon oxide by CVD. Then, heat treatment is performed. Thereby, the n⁺-type region 64 is formed self-aligningly by the n-type impurity included inside the conductive member 62 diffusing into the silicon substrate 10; and the p⁺-type region 65 is formed self-aligningly by the p-type impurity included inside the conductive member 62 diffusing into the silicon substrate 10.

Then, as shown in FIG. 13B, the mask film 96 is patterned to expose the region where the STI 45 is to be formed. Then, the recess 97 is formed in the upper surface of the epitaxial layer 90 by performing RIE of the silicon using the patterned mask film 96 as a mask.

Continuing as shown in FIG. 13C, silicon oxide is deposited by CVD. Then, the upper surface is planarized by performing CMP using the silicon nitride layer 92 as a stopper. Then, the silicon nitride layer 92 is removed. Thereby, the STI 45 is formed inside the recess 97.

The subsequent processes are similar to those of the second embodiment described above. Thus, the semiconductor device 5 according to the embodiment is manufactured. Otherwise, the manufacturing method of the embodiment is similar to that of the second embodiment (referring to FIG. 5A to FIG. 6D).

According to the embodiment, the ground potential can be applied to the interior of the silicon substrate 10 via the conductive member 62 and the p⁺-type region 65. Thereby, the parasitic resistance between the silicon substrate 10 and the ground potential can be reduced; and the potential of the silicon substrate 10 interior can be stabilized. As a result, the immunity to latchup can be improved.

Otherwise, the configuration, the operations, and the effects of the embodiment are similar to those of the fourth embodiment described above.

### Sixth Embodiment

A sixth embodiment will now be described.

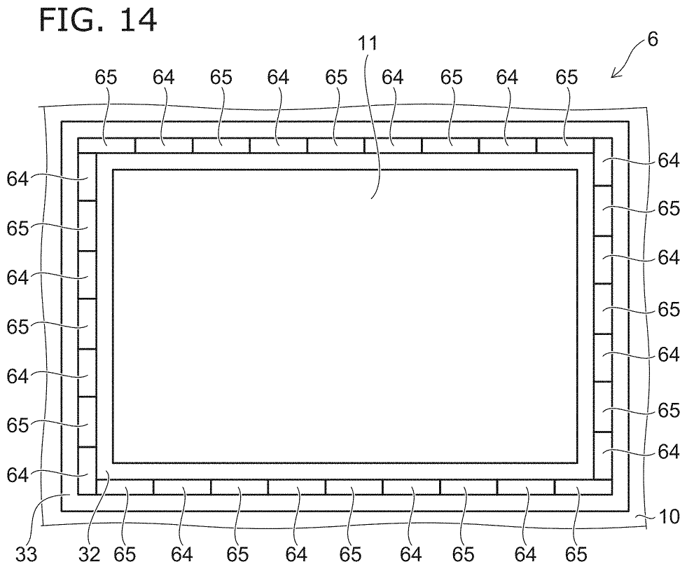

FIG. 14 is a plan view showing a semiconductor device according to the embodiment.

FIG. 14 shows the n⁺-type regions 64 and the p⁺-type regions 65; and the conductive member 31 is not illustrated.

In the semiconductor device 6 according to the embodiment as shown in FIG. 14, the multiple n⁺-type regions 64 and the multiple p⁺-type regions 65 are provided directly under the conductive member 31 disposed at the periphery of the element 11 (referring to FIG. 4). The n⁺-type region 64 and the p⁺-type region 65 are arranged alternately along the lower end 31b of the conductive member 31. On the other hand, at the periphery of the element 12, the conductive member 36, etc. (referring to FIG. 4) may be provided; or the insulating member 61 (referring to FIG. 9) may be provided.

A method for manufacturing the semiconductor device according to the embodiment will now be described.

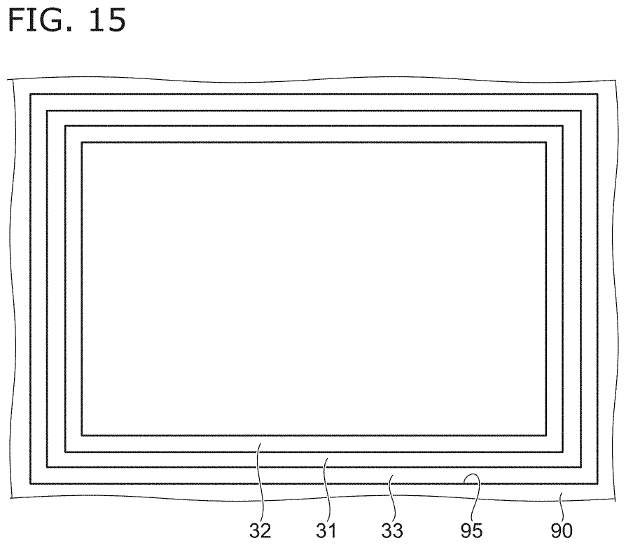

FIG. 15 is a plan view showing the method for manufacturing the semiconductor device according to the embodiment.

First, the deep trench 95 is formed in the silicon substrate 10 and the epitaxial layer 90 by performing the processes shown in FIGS. 5A to 5D. Then, the insulating films 32, 33, 37, and 38 are formed on the side surface of the deep trench 95.

Then, as shown in FIG. 15, the conductive member 31 is formed inside the deep trench 95 by performing the process shown in FIG. 6A. However, the embodiment differs from the second embodiment in that undoped polysilicon to which an impurity is not added is deposited.

Continuing, similarly to the processes shown in FIGS. 12B and 12C, an n-type impurity and a p-type impurity are selectively implanted into the conductive member 31 made of undoped polysilicon (referring to FIG. 15). At this time, as shown in FIG. 14, the regions where the n-type impurity is implanted and the regions where the p-type impurity is implanted are arranged alternately. Then, by performing heat treatment, the n⁺-type region 64 and the p⁺-type region 65 are formed self-aligningly directly under the conductive member 31 by causing the n-type impurity and the p-type impurity inside the conductive member 31 to diffuse into the silicon substrate 10.

The subsequent processes are similar to those of the second embodiment. Thus, the semiconductor device 6 according to the embodiment is manufactured.

In the embodiment as well, similarly to the fifth embodiment, the electrons that are introduced to the silicon substrate 10 due to the negative freewheeling current can be ejected via the n⁺-type region 64 and the conductive member 31; and the potential of the silicon substrate 10 can be stabilized via the conductive member 31 and the p⁺-type region 65.

Otherwise, the configuration, the operations, and the effects of the embodiment are similar to those of the second embodiment described above.

Although examples are shown in the embodiments described above in which the n⁺-type region contacts the lower end of the conductive member, this is not limited thereto. For example, the n⁺-type region may contact the side surface of the conductive member. Although examples are shown in the embodiments described above in which an insulating film is provided between the n⁺-type region and the element, this is not limited thereto; and the n⁺-type region and the element may be insulated using any method.

According to the embodiments described above, a semiconductor device can be realized in which downsizing is possible. While certain embodiments have been described, these embodiments have been presented by way of example only, and are not intended to limit the scope of the inventions.

Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a first semiconductor layer of a first conductivity type;
a first element including a second semiconductor layer of a second conductivity type, at least a portion of the first element being formed in an upper layer portion of the first semiconductor layer;
a second element including a third semiconductor layer of the second conductivity type, at least a portion of the second element being formed in an upper layer portion of the first semiconductor layer;
a first conductive member disposed in the first semiconductor layer between the first element and the second element, an upper end of the first conductive member being positioned higher than an upper end of the second semiconductor layer, a lower end of the first conductive member being positioned lower than a lower end of the second semiconductor layer and a lower end of the third semiconductor layer; and
a first semiconductor region provided inside the first semiconductor layer, the first semiconductor region being of the second conductivity type and contacting the first conductive member.

2. The device according to claim 1, wherein
the first conductivity type is a p-type, and
the second conductivity type is an n-type.

3. The device according to claim 2, wherein 0 V or a positive potential is applied to the first conductive member.

4. The device according to claim 1, wherein the first conductive member includes silicon including an impurity forming donors.

5. The device according to claim 1, wherein the first conductive member includes a metal.

6. The device according to claim 1, wherein the first element is a double-diffused metal-oxide-semiconductor field-effect transistor.

7. The device according to claim 6, wherein a negative freewheeling current is input to a drain of the double-diffused metal-oxide-semiconductor field-effect transistor.

8. The device according to claim 1, wherein the first semiconductor region contacts the lower end of the first conductive member.

9. The device according to claim 1, further comprising an insulating film provided between the semiconductor substrate and a side surface of the first conductive member.

10. The device according to claim 1, wherein the first conductive member surrounds the first element when viewed from above.

11. The device according to claim 10, further comprising:
a second conductive member surrounding the second element when viewed from above, an upper end of the second conductive member being exposed at an upper surface of the first semiconductor layer, a lower end of the second conductive member being positioned lower than the lower end of the second semiconductor layer and the lower end of the third semiconductor layer; and
a second semiconductor region provided inside the first semiconductor layer, the second semiconductor region being of the second conductivity type and contacting the second conductive member.

12. The device according to claim 10, further comprising a first insulating member surrounding the second element when viewed from above, an upper end of the first insulating member being exposed at an upper surface of the first semiconductor layer, a lower end of the first insulating member being positioned lower than the lower end of the second semiconductor layer and the lower end of the third semiconductor layer.

13. The device according to claim 1, further comprising:
a first insulating member surrounding the first element when viewed from above, an upper end of the first insulating member being exposed at an upper surface of the first semiconductor layer, a lower end of the first insulating member being positioned lower than the lower end of the second semiconductor layer and the lower end of the third semiconductor layer; and
a second insulating member surrounding the second element when viewed from above, an upper end of the second insulating member being exposed at the upper surface of the first semiconductor layer, a lower end of the second insulating member being positioned lower than the lower end of the second semiconductor layer and the lower end of the third semiconductor layer,
the first conductive member being disposed between the first insulating member and the second insulating member.

14. The device according to claim 13, wherein a configuration of the first conductive member is a flat plate configuration spreading in a direction orthogonal to a direction from the first element toward the second element.

15. The device according to claim 13, further comprising:
a second conductive member disposed in the first semiconductor layer between the first element and the second element, an upper end of the second conductive member being exposed at the upper surface of the first semiconductor layer, a lower end of the second conductive member being positioned lower than the lower end of the second semiconductor layer and the lower end of the third semiconductor layer; and
a second semiconductor region provided inside the first semiconductor layer, the second semiconductor region being of the second conductivity type and contacting the second conductive member.

16. The device according to claim 15, wherein configurations of the first conductive member and the second conductive member are flat plate configurations arranged to be parallel to each other.

17. The device according to claim 1, further comprising a second semiconductor region provided inside the first semiconductor layer, the second semiconductor region being of the first conductivity type and contacting the first conductive member, an impurity concentration of the second semiconductor region being higher than an impurity concentration of the first semiconductor layer.

18. The device according to claim 17, wherein the first semiconductor region and the second semiconductor region are arranged alternately along the lower end of the first conductive member.

19. A semiconductor device, comprising:
a first semiconductor layer of a first conductivity type;
a first element including a second semiconductor layer of a second conductivity type, at least a portion of the first element being formed in an upper layer portion of the first semiconductor layer;
a second element including a third semiconductor layer of the second conductivity type, at least a portion of the second element being formed in an upper layer portion of the first semiconductor layer;
an insulating film disposed in the first semiconductor layer between the first element and the second element, an upper end of the insulating film being positioned higher than an upper end of the second semiconductor layer, a lower end of the insulating film being positioned lower than a lower end of the second semiconductor layer and a lower end of the third semiconductor layer; and
a first semiconductor region contacting the lower end of the insulating film and being of the second conductivity type, a reference potential being applied to the first semiconductor region.

20. The device according to claim 19, wherein
the first conductivity type is a p-type,
the second conductivity type is an n-type, and
the reference potential is a ground potential or a positive potential.
